(19) United States
(12) Patent Application Publication
(10) Pub. No.: US 2023/0280273 A1
(43) Pub. Date: Sep. 7, 2023

(54) BACTERIAL DETECTION ELEMENT, BACTERIA DETECTION SENSOR, ELECTRONIC DEVICE AND METHOD FOR DETECTING BACTERIA USING THE SAME

(71) Applicant: EMTAKE INC., Seoul (KR)

(72) Inventor: Yongho CHO, Hanam-si (KR)

(73) Assignee: EMTAKE INC., Seoul (KR)

(21) Appl. No.: 17/705,061

(22) Filed: Mar. 25, 2022

(30) Foreign Application Priority Data
Mar. 2, 2022 (KR) 10-2022-0026529

(51) Int. Cl. G01N 21/64; G01N 21/33; H01L 31/0304

(52) U.S. Cl. CPC G01N 21/6428; G01N 21/33; H01L 31/03044; H01L 31/03048

(57) ABSTRACT

An electronic device provided with a bacteria detection element and a bacteria detection sensor, and a method of detecting bacteria by using the same are proposed. The electronic device provided with the bacteria detection element and the bacteria detection sensor are disclosed such that a first semiconductor layer, a light absorption layer, and a second semiconductor layer are provided to have respective inclined surfaces in a mesa structure, the respective inclined surfaces are passivated by an oxide, and the light absorption layer is formed as a multi-layer. The electronic device having the bacteria detection sensor provides a function capable of detecting the bacteria and even sterilizing the detected bacteria. In particular, a UVC light source and a UVA light source are mounted on a single printed circuit board, whereby the electronic device may be produced in a small size and may reduce production costs.

### CROSS REFERENCE TO RELATED APPLICATION

The present application claims priority to Korean Patent Application No. 10-2022-0026529, filed Mar. 2, 2022, the entire contents of which is incorporated herein for all purposes by this reference.

### BACKGROUND OF THE INVENTION

### Field of the Invention

The present disclosure relates to an electronic device provided with a bacteria detection element and a bacteria detection sensor, and a method of detecting bacteria by using the same and, more particularly to an electronic device provided with a bacteria detection element and a bacteria detection sensor, and a method of detecting bacteria by using the same, the bacteria detection element including a light absorption layer formed as a multi-layer, allowing material composition ratios of the respective layers formed as the multi-layer to be different from each other so that various substances are accurately detectable, having an inclined surface formed with an area that becomes narrower from a first semiconductor layer to a second semiconductor layer, and covering the inclined surface to be exposed with an oxide.

### Description of the Related Art

In general, as an element for converting light energy into electrical energy, a bacteria detection element has advantages of high sensitivity of operating wavelengths, fast response speed, and minimum noise, so the bacteria detection element is widely used as an element for detecting light signals in various fields.

FIG. 1 is a cross-sectional view illustrating a general bacteria detection element. Referring to FIG. 1, the bacteria detection element 1 may include a substrate 2, a first semiconductor layer 3, a light absorption layer 4, and a second semiconductor layer 5. The substrate 2 may be a sapphire substrate or a GaN substrate, the first semiconductor layer 3 may be a semiconductor layer to which n-type impurities are added at a high concentration, and the second semiconductor layer 5 may be a semiconductor layer to which p-type impurities are added. The light absorption layer 4 is a layer that forms an electron-hole pair by absorbing light incident from outside, and may absorb light corresponding to an energy band gap of a material constituting the light absorption layer 4. For example, when sunlight is incident, the light absorption layer 4 may absorb only the same wavelength as the energy band gap, and may allow other wavelengths to pass through, or not to pass through the same.

Meanwhile, in the atmosphere, there are substances suspended in the air, the substances including fine dust, wood chip dust, fungus, and aerosols composed of biological particles such as materials due to bioterrorism using artificially generated toxins and pollutants, thereby resulting in a detrimental effect on the health of humans, animals, and plants. In order to detect harmful substances suspended in the air, laser-induced fluorescence technology, photo multiplier tube (PMT) technology, and technology using UV-enhanced Si have been proposed. However, there are problems in that these technologies may have to be implemented with expensive equipment, may allow detection only at a laboratory level due to an issue such as responding to visible light, or may take a significant time for analysis, thereby being unable to be used universally in daily life.

### DOCUMENTS OF RELATED ART

Korea Application Publication No. 10-2021-0135821 (published on Nov. 16, 2021)

### SUMMARY OF THE INVENTION

An objective of the present disclosure is to solve the above-described problems and provide an electronic device provided with a bacteria detection element and a bacteria detection sensor, and a method of detecting bacteria by using the same, wherein harmful substances attached to a test object may be quickly and accurately detected, and the electronic device is usable in daily life at a relatively low price.

Another objective of the present disclosure is to provide an electronic device provided with a bacteria detection element and a bacteria detection sensor, and a method of detecting bacteria by using the same, the bacteria detection element including nitride-based semiconductor with a PIN structure capable of efficiently detecting fluorescence signals in a wavelength band of 340 to 350 nm.

Yet another objective of the present disclosure is to provide an electronic device provided with a bacteria detection sensor, and a method of detecting bacteria by using the same, wherein the bacteria detection sensor is implemented as an AlGaN-based semiconductor capable of replacing a conventional PMT, and is able to provide both bacteria detection and bacteria sterilization functions.

The above objectives of the present disclosure may be achieved by a bacteria detection element, including: a substrate; a first semiconductor layer and a second semiconductor layer configured to be arranged on the substrate and made of a nitride-based material; and a light absorption layer configured to be arranged between the first semiconductor layer and the second semiconductor layer and made of the nitride-based material, so as to absorb light of multiple wavelengths, wherein the light absorption layer includes: a first light absorption layer configured to absorb light of a first wavelength; a second light absorption layer configured to absorb light of a second wavelength different from the first wavelength; and a third light absorption layer configured to absorb light of a third wavelength different from the first and second wavelengths, the first to third light absorption layers are configured to be formed of a single component of AlGaN, be arranged between the first semiconductor layer and the second semiconductor layer, and respectively have Al composition ratios increasing in an order of the first light absorption layer, the third light absorption layer, and the second light absorption layer, so as to absorb the light of the first to third wavelengths incident on the first semiconductor layer or the second semiconductor layer separately from each other, the first semiconductor layer, the light absorption layer, and the second semiconductor layer are respectively provided with inclined surfaces in a mesa structure, and the inclined surfaces are passivated with an oxide.

Still another objective of the present disclosure is achievable through the bacteria detection sensor configured to include a plurality of bacteria detection elements formed on a same substrate by a same semiconductor process. It is natural that each of the plurality of bacteria detection elements constituting the bacteria monitoring sensor may have a light absorption layer formed in a different size or in a different composition ratio of materials forming the light absorption layer.

Still another objective of the present disclosure is achievable through an electronic device provided with a bacteria detection sensor, the electronic device including a casing provided with a window on one side thereof, and including, in the casing: the bacteria detection sensor including a bacteria detection element; a UVA power controller configured to control power supplied to the bacteria detection element on or off; an excitation light emission part configured to illuminate with a UVC light source; a UVC power controller configured to control power supplied to the excitation light emission part on or off; an amplifier configured to amplify a signal output from the bacteria detection sensor; an AD converter configured to convert the signal amplified by the amplifier into a digital signal; and a system controller configured to generate a control signal for controlling the UVA power controller, the UVC power controller, and the AD converter, and output the digital signal output from the AD converter to outside.

Still another objective of the present disclosure is achievable through a method of detecting whether bacteria are attached on a test object, the method having the test object and the bacteria provided with a characteristic of expressing a fluorescence wavelength in a same range when being illuminated with a UVC light source, and including: a first step of calculating a first difference value (δ1) by subtracting an intensity value of a fluorescence wavelength measured at time t1 after illumination with the UVC light source from a highest value of a fluorescence wavelength expressed by illuminating the bacteria with the UVC light source, and calculating a second difference value (δ2) by subtracting the intensity value of the fluorescence wavelength measured at time t1 after the illumination with the UVC light source from a highest value of a fluorescence wavelength expressed by illuminating the test object to which the bacteria are not attached with the UVC light source; a second step of calculating a third difference value (δ3) by subtracting the intensity value of the fluorescence wavelength measured at time t1 after the illumination with the UVC light source from a highest value of the fluorescence wavelength expressed by illuminating the test object, whose attachment of the bacteria is not confirmed, with the UVC light source; and a third step of determining whether the bacteria are attached to the test object in the third step by using the first difference value, the second difference value, and the third difference value.

Conventionally, in a commercialized bacteria detection sensor composed of a semiconductor element, a method of simultaneously detecting light within a certain wavelength range is adopted, instead of detecting only a particular wavelength expressed by bacteria. In a case of bacteria, a fluorescence wavelength that is emitted while receiving excitation light and resonating has different characteristics for each bacteria. Since the conventional bacteria detection sensor concurrently receives wavelengths within the certain wavelength range, there is a problem that detection accuracy is deteriorated due to the weak intensity of fluorescence signals.

In contrast, in the electronic device provided with the bacteria detection element and the bacteria detection sensor, and the method of detecting the bacteria by using the same, since it is possible for a light absorption layer to be produced to detect only a fluorescence expression frequency of specific bacteria by controlling composition ratios of a plurality of substances, the detection accuracy may be increased. In addition, the bacteria detection sensor according to the present disclosure is formed to have the inclined surface in a mesa structure, and is configured such that an active layer to be exposed is passivated with an oxide so as to reduce the leakage current, whereby the measurement sensitivity may be increased.

The electronic device provided with the bacteria detection sensor according to the present disclosure provides functions capable of not only detecting bacteria but also sterilizing the detected bacteria. In particular, by mounting a UVC light source and a UVA light source on a single printed circuit board, the electronic device may be produced in a small size, thereby reducing the production cost.

When the bacteria detection method provided in the present disclosure is applied, whether or not bacteria are attached to a corresponding test object may be detected even in a case of the test object and bacteria that respectively express the same fluorescence wavelengths in UVC.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a cross-sectional view illustrating a general bacteria detection element.

FIG. 2 is a cross-sectional view illustrating a bacteria detection element according to a first exemplary embodiment of the present disclosure.

FIG. 3 is a cross-sectional view of a bacteria detection element according to an exemplary embodiment of the present disclosure.

FIG. 4 is a graph illustrating an absorption-wavelength relationship of an AlGaN thin film according to each composition ratio.

FIG. 5 is a layout view of a bacteria detection sensor composed of a plurality of identical bacteria detection elements.

FIG. 6 is a layout view of a bacteria detection sensor in which bacteria detection elements respectively having different sizes of light absorption layers are formed in one package.

FIG. 7 is a layout view of a bacteria detection sensor in which a first column is formed of bacteria detection elements having a first light absorption layer, and a second column is formed of bacteria detection elements having a second light absorption layer.

FIG. 8 is a block diagram of a bacteria detection sensor provided with focusing lenses.

FIG. 9 is an intensity graph of fluorescence spectra excited by various enzymes when being illuminated with a 266 nm laser.

FIG. 10 is an intensity graph of normalized fluorescence spectra that are resonated, fluoresced, or scattered by various bacteria when being illuminated with a 278 nm (UVC) laser.

FIGS. 11A to 11C are graphs of intensity changes measured over time after each of E. coli, protein, and protein with E. coli is illuminated with a UVC light source.

FIGS. 12A to 12C are graphs of intensity changes measured over time when illuminating each of E. coli, protein, and protein with E. coli twice with the UVC light source, the respective illuminating having a rest period therebetween.

FIG. 13 is a system configuration diagram of an electronic device provided with the bacteria detection sensor according to the present disclosure.

FIG. 14 is an exemplary view in which an excitation light emission part and the bacteria detection sensor are mounted on a single printed circuit board in the electronic device shown in FIG. 3.

FIG. 15 is a driving timing diagram of the excitation light emission part and the bacteria detection sensor constituting the electronic device shown in FIG. 13.

FIG. 16 is a driving timing diagram of the excitation light emission part and bacteria detection sensor for applying the electronic device shown in FIG. 13 to a test object and bacteria that express the same range of wavelengths in response to UVC light.

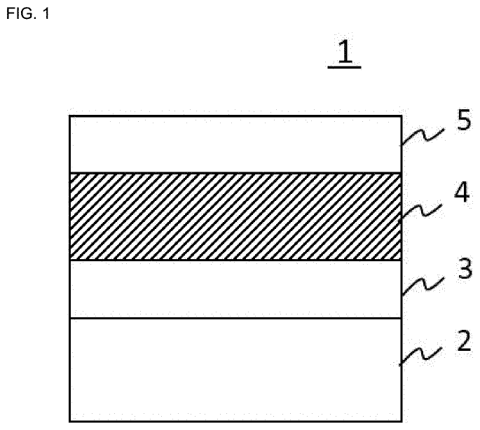

### DETAILED DESCRIPTION OF THE INVENTION

The terminology used herein is for the purpose of describing particular exemplary embodiments only and is not intended to limit the present disclosure. As used herein, the singular forms are intended to include the plural forms as well, unless the context clearly indicates otherwise. It will be further understood that the terms “comprise”, “include”, “have”, etc. when used in the present specification, specify the presence of features, integers, steps, operations, elements, components, and/or combinations thereof stated in the specification, but do not preclude the possibility of the presence or addition of one or more other features, integers, steps, operations, elements, components, and/or combinations thereof.

In addition, in the present specification, “on or on top of” means to be positioned on an upper side or a lower side of a target part and this means that it is not necessarily positioned on the upper side with respect to the direction of gravity. That is, the term “on or on top of” referred to in the present specification includes not only a case of being positioned above or below the target part, but also a case of being positioned in front or behind the target part.

In addition, in a case where it is said that a part of a region, plate, etc. is positioned “on or on top of” another part, the case includes not only a case of being positioned in contact with or spaced “on or on top of” another part but also a case of being positioned in the middle or in between.

In addition, in the present specification, when one component is referred to as “connected to”, “in contact with” the other component, or the like, the one component may be directly connected to or directly in contact with the other component, but it should be understood that, unless specifically stated to the contrary, the one component may be connected to or in contact with the other component through another component in the middle therebetween.

In addition, in the present specification, it will be understood that, although the terms first, second, etc. may be used herein to describe various components, these components should not be limited by these terms. These terms are only used for the purpose of distinguishing one component from another component.

First, the terms will be defined. In the present disclosure, the terms called a bacteria detection element and a bacteria detection sensor are used. The bacteria detection element refers to a semiconductor element in which a first semiconductor layer, a light absorption layer, and a second semiconductor layer are sequentially stacked vertically on a substrate, and the bacteria detection sensor refers to a sensor provided as a semiconductor chip provided in an integrated package including one or more bacteria detection elements. It is natural that the bacteria detection element is provided with a first electrode for applying electricity to a first semiconductor layer and a second electrode for applying electricity to a second semiconductor layer. When describing the bacteria detection element and the bacteria detection sensor in terms of circuit elements, the bacteria detection element may be described as a circuit element configured to output a current according to the amount of light received by the light absorption layer, and the bacteria detection sensor may be described as a circuit element in which a resistor having a predetermined size is installed between PN terminals of the bacteria detection element and the bacteria detection element outputting a voltage applied to both terminals of the corresponding resistor and the resistor are packaged.

Hereinafter, preferred exemplary embodiments, advantages and features of the present disclosure will be described in detail with reference to the accompanying drawings.

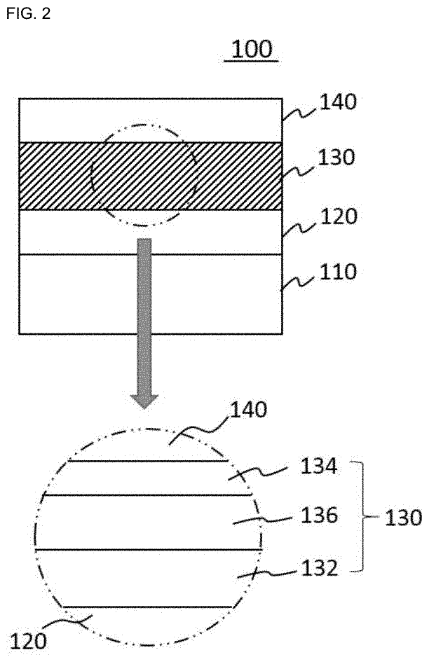

FIG. 2 is a cross-sectional view illustrating a bacteria detection element according to a first exemplary embodiment of the present disclosure. Referring to FIG. 2, a bacteria detection element 100 may include a substrate 110, a first semiconductor layer 120, a light absorption layer 130, and a second semiconductor layer 140.

The substrate 110 is a substrate suitable for growing a semiconductor single crystal, and may be formed by using, for example, a light-transmitting material including sapphire (Al₂O₃). The substrate 110 may be formed of at least one of Si, GaAs, Si, GaP, InP, Ge, Ga203, ZnO, GaN, SiC, and AlN, but is not limited thereto. In addition, the substrate 110 may use materials capable of improving thermal stability by facilitating heat dissipation.

The first semiconductor layer 120 may be arranged on the substrate 110. When being implemented as an n-type semiconductor layer, for example, the first semiconductor layer 120 may be made of a semiconductor material selected from, for example, GaN, AlN, AlGaN, InGaN, InNInAlGaN, AlInN, and the like, the semiconductor material having a composition formula of InAlyGa1−x−yN (0=x≤1, 0≤y≤1, 0≤x+y≤1), and may be doped with an n-type dopant such as Si, Ge, Sn, Se, and Te.

In this case, an undoped semiconductor layer (not shown) that is not doped with a dopant may be arranged between the first semiconductor layer 120 and the substrate 110. The undoped semiconductor layer is a layer formed to improve the crystallinity of the first semiconductor layer 120, and may be the same as the first semiconductor layer 120, except that the n-type dopant is not doped and thus has lower electrical conductivity than that of the first semiconductor layer 120, but is not limited thereto.

The light absorption layer 130 may be arranged between the first semiconductor layer 120 and the second semiconductor layer 140. First, the light absorption layer 130 is a layer that forms an electron-hole pair by absorbing light incident from outside, and may be an intrinsic semiconductor layer or a semiconductor layer in which an n-type impurity is added at a lower concentration than that of the first semiconductor layer 120.

The light absorption layer 130 may be made of a semiconductor material selected from, for example, GaN, AlN, AlGaN, InGaN, InN, InAlGaN, AlInN, and the like, the semiconductor material having a composition formula of InxAlyGa1−x−yN (0=x≤1, 0≤y≤1, 0≤x+y≤1), as an example. In the exemplary embodiment, the light absorption layer 130 will be described as being formed of GaN or AlGaN. Here, the light absorption layer 130 may include first to third light absorption layers 132, 134, and 136.

An example in which the light absorption layer 130 is formed of aluminum gallium nitride (AlGaN) will be described.

The first light absorption layer 132 may be arranged adjacent to the first semiconductor layer 120. In this case, the first light absorption layer 132 may absorb light of a first wavelength longer than those of the second and third light absorption layers 134 and 136. For example, the first light absorption layer 132 has a composition formula of AlyGa1−yN (y≈0), and the Al composition ratio (y) may be close to “0”.

In addition, the second light absorption layer 134 may be arranged adjacent to the second semiconductor layer 140. In this case, the second light absorption layer 134 may absorb light of a second wavelength shorter than those of the first and third light absorption layers 132 and 136. For example, the second light absorption layer 134 has a composition formula of AlyGa1−yN (y≈1), and the Al composition ratio (y) may be close to “1”.

Finally, the third light absorption layer 136 may be arranged between the first and second light absorption layers 132 and 134. In this case, the third light absorption layer 136 may have an Al composition ratio in a range between the Al composition ratios of the first and second light absorption layers 132 and 134.

As a result, the Al composition ratio (y) may be determined such that the first light absorption layer 132 has the lowest value, the second light absorption layer 134 has the highest value, and the third light absorption layer 136 has the values in the range between the Al composition ratios of the first and second light absorption layers 132 and 134. Accordingly, the first light absorption layer 132 may absorb the light of the first wavelength that has passed through the second and third light absorption layers 134 and 136, the third light absorption layer 136 may absorb the light of the third wavelength that has passed the second light absorption layer 134, and the second light absorption layer 134 may absorb the light of the second wavelength while allowing the light of the first and third wavelengths to pass therethrough.

The second semiconductor layer 140 may be arranged on the light absorption layer 130. In this case, the second semiconductor layer 140 may be implemented as a p-type semiconductor layer. When being implemented as the p-type semiconductor layer, the second semiconductor layer 140 may be made of a semiconductor material selected from, for example, GaN, AlN, AlGaN, InGaN, InN, InAlGaN, AlInN, and the like, the semiconductor material having a composition formula of InxAlyGa1−x−yN (0=x≤1, 0≤y≤1, 0≤x+y≤1), and may be doped with a p-type dopant such as Mg, Zn, Ca, Sr, and Ba.

Electrodes (not shown) for applying power may be arranged on the first semiconductor layer 120 and the second semiconductor layer 140, but the present disclosure is not limited thereto.

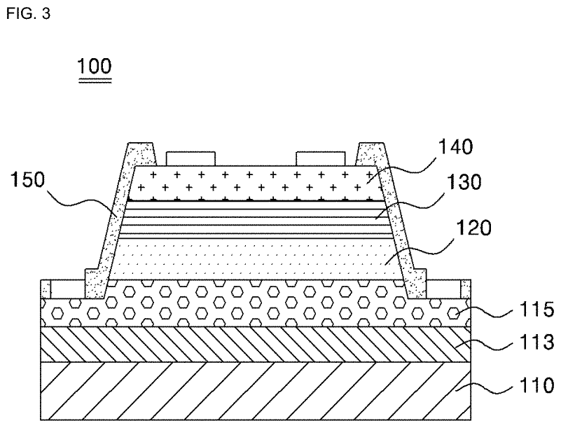

FIG. 3 is a cross-sectional view of the bacteria detection element according to the exemplary embodiment of the present disclosure. A sapphire substrate 110 is used as the substrate, and the first semiconductor layer 120 is formed of n-AlGaN. A buffer layer (AlN template) 113 and an undoped semiconductor layer (AlGaN) 115 are formed between the substrate 110 and the first semiconductor layer 120. The buffer layer (AlN template) 113 is a layer that helps the growth of the undoped semiconductor layer 115.

In a sensor structure for detecting 340 nm fluorescence signals, GaN has an energy bandgap of Eg=3.45 eV and has a wavelength of about 365 nm. When a GaN thin film is used in the sensor structure, the GaN thin film absorbs a 340 nm wavelength, so that light reception efficiency may be reduced. Accordingly, AlGaN and AlN thin films should be used, but it is difficult to obtain high quality AlN and AlGaN thin films due to a lattice constant difference between a sapphire substrate and an AlN layer, and due to pre-reaction between Al and NH3.

In the present disclosure, a first AlN layer is grown on the sapphire substrate, and in order to grow a high-temperature second AlN thin film thereon, the first AlN growth temperature is firstly changed up to 800° C. to 1,100° C., and then the second AlN thin film is grown and formed at 1,250° C. (first AlN growth pressure 50 torr, Al=13 sccm, NH3=100 sccm, and second AlN growth pressure 40 torr, Al=20 sccm, NH3=135 sccm).

It is confirmed that using the GaN substrate rather than the sapphire substrate is more advantageous for detecting 340 nm fluorescence signals.

The second semiconductor layer 140 is formed of p-AlGaN, and is formed next to the light absorption layer 130. The incident UV light is absorbed into an l-GaN layer through a p-GaN layer positioned on a top side of a GaN-based photosensor structure, and affects the reactivity and quantum efficiency characteristics of a light-receiving element according to the doping concentration and thickness of the p-GaN layer.

As a result of simulating punch-through characteristics according to the p-GaN doping concentration, assuming that the maximum magnitude of an electric field is 3 MV/cm, it may be confirmed that the lower the doping concentration, the more punch-through phenomena occur at a very low voltage. Accordingly, it is confirmed that an increase in the thickness of the p-GaN layer or the doping concentration of 1×10¹⁸ cm⁻³ or more should be obtained in order to avoid the punch-through phenomena.

In the present disclosure, a GaN buffer layer with a thickness of 25 nm is grown at 520° C. on a sapphire substrate by using an MOCVD growth method, and then the temperature is raised to 1,040° C. Thereafter, an undoped GaN thin film with a thickness of 0.3 μm is grown. In addition, first, a u-GaN thin film having a thickness change from 10 nm to 18 nm is grown on 0.3 μm thick u-GaN in order to grow a Mg delta doped p-GaN thin film. Next, nitridation is performed for 30 seconds in order to stabilize a GaN surface. Then, the Mg delta doped p-GaN thin film is grown while changing the time, required to flow only an Mg source that affects hole concentration, to 16.5 seconds, 33 seconds, and 48 seconds. The Mg delta doped p-GaN thin film is grown by using the 70-loop, and the total thickness of the p-GaN thin film grown according to the time change of the Mg delta doping is 0.3 to 0.6 μm. The sample with the Mg delta doping provides a hole concentration of 2.782×10¹⁷ cm⁻³ and resistance of 1.52 Ω·cm, compared to a hole concentration of 2.17×10¹⁷ cm⁻³ and resistance of 2.15 Ω·cm for samples without the Mg delta doping. Accordingly, compared to a bulk p-GaN surface, it is confirmed that the hole concentration, resistance, and surface roughness of the p-GaN thin film with the Mg delta doped layer are improved.

Conventionally, when the second semiconductor layer 140 and the light absorption layer 130 are formed, the second semiconductor layer 140 and the light absorption layer 130 are grown by using a one-step temperature condition, but in the present disclosure, temperature changes such as low-high-low temperature are performed so that impurity content is minimized during epitaxial growth.

In addition, in order to reduce the leakage current and secure uniform electric field distribution even at high voltage, the bacteria detection element according to the present disclosure is formed in a PIN structure based on AlGaN in a mesa-structure having bevel angled side walls. The mesa structure refers to an LED structure having an etched surface. A mesa is a table-shaped terrain with a flat top and a steep slope around the terrain. In the LED structure, an active layer is exposed on a mesa surface, and in the present disclosure, the active layer is passivated with an oxide (e.g., silicon oxide (SiO₂) 150). A PIN junction refers to a junction in which a rather wide intrinsic semiconductor layer is provided between pn junctions.

In the present disclosure, in the case of AlGaN, high-temperature growth is advantageous in order to increase a migration length of Al on the surface of the sapphire substrate. In addition, optimum conditions are established through controlling growth pressure, a V/III ratio, and a flow rate of total source gas, in order to grow a high-quality AlGaN thin film in a direction of maximally increasing the migration length by controlling the pressure of a reactor or controlling the flow rate of the source gas and the V/III ratio.

An epitaxial structure of an absorption layer having a multi-AlGaN/AlGaN-layer structure for controlling 17% or more strain in the absorption layer is developed, and the epitaxial structure having multiple AlGaN/AlGaN absorption layers for improving light-receiving efficiency is designed and developed by optimizing conditions such as Al composition ratios, thicknesses, and the number of cycles of AlGaN well and AlGaN barrier.

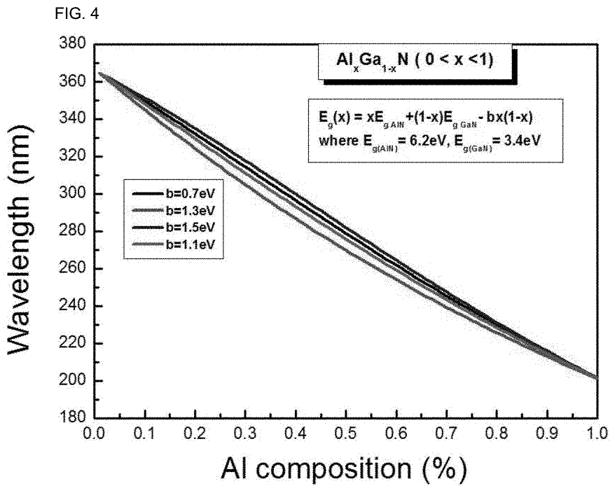

Light signals of various wavelengths may be detected by forming the light absorption layer 130 as the multi-layer. In order to detect the light signals in an ultraviolet region of 200 to 400 nm, the light absorption layer 130 is implemented by using the group III-V compound materials including AlN (energy band gap Eg=6.0 eV), GaN (Eg=3.45 eV), and InN (Eg=0.75 eV). In particular, in a photosensor having the PIN structure, AlxGa1−xN material is used for the light absorption layer 130, and the photosensor is implemented so that light absorption wavelengths are controllable according to an Al composition ratio X. FIG. 4 is a graph illustrating an absorption-wavelength relationship of the AlGaN thin film according to each composition ratio. As shown in the graph of FIG. 4, it may be confirmed that an Al_{0.17}Ga_{0.83}N thin film having an Al composition ratio of about 17% is required in order to detect signals in a 340 nm wavelength band. As will be described later, since bacteria such as E. coli, or tryptophan excites the wavelength of 340 nm, the Al composition ratio is preferably determined to have a value of about 17%.

In order to optimize the epitaxial structure for producing the 340 nm light-receiving element shown in FIG. 4, first, AlGaN thin film growth and characteristics thereof are analyzed by changing growth pressure. In order to confirm Al composition ratios, after growing a u-GaN thin film on a sapphire substrate, the AlGaN thin film is grown at a growth temperature of 1,040° C. by changing growth pressure by 200 to 60 torr and by changing a NH3 flow rate by 12 to 8 slm. Table 1 is a table of Al composition ratios of samples grown according to the growth pressure change and NH3 flow rate change, and the Al composition ratios are measured by using XRD.

TABLE 1

| | Growth | NH3 flow | Al |
|---|---|---|---|
| Sample # | pressure (torr) | rate (slm) | composition (%) |
| n-AlGaN-1a | 200 | 12 | 7.3 |
| n-AlGaN-2a | 100 | 12 | 12.36 |
| n-AlGaN-3a | 60 | 12 | 15.14 |
| n-AlGaN-4a | 60 | 8 | 17 |

It is confirmed that a PL result of a peak wavelength of each sample having an Al composition ratio is shown as follows: (a) in case of the Al composition ratio of 7.2%, the peak wavelength is about 350 nm, (b) in case of 12.3%, the peak wavelength is 342 nm, (c) in case of 15.14%, the peak wavelength is 340 nm, and (d) in case of 17%, the peak wavelength is about 338 nm. In the Al composition ratios of the AlGaN thin film, there is a slight difference between a numeric value obtained by calculation and a numeric value obtained by XRD and PL, and in such a result, the difference is generated due to the fact that strain occurs at an interface between (Al)GaN and GaN/sapphire in an actually grown thin film. Meanwhile, it is confirmed that there is no problem to grow the element structure by using an AlGaN thin film having an Al composition ratio in a range of 12 to 15% lower than the Al composition ratio of 17% calculated in FIG. 4, in order to detect fluorescence signals in the 340 nm wavelength band to be obtained in the present disclosure.

As described so far, the bacteria detection sensor may be configured in various forms by using the bacteria detection element provided with the light absorption layer formed by the multi-layer, and provided with the mesa structure of the PIN junction. A bacteria detection sensor with the simplest structure is formed by packaging a single bacteria detection element. However, when a small amount of harmful substances contained in the atmosphere is detected by the bacteria detection sensor composed of only one bacteria detection element, the detection accuracy may be reduced. Unlike ordinary particles, bacteria and fungi, which are microbes causing food poisoning, express fluorescence wavelengths when excitation light is incident from outside, so whether or not the bacteria and fungi are present may be determined by detecting the fluorescence wavelengths. However, since the intensity of the fluorescence wavelengths is weak, there is a problem in that it is difficult to detect the fluorescence wavelengths with the currently commercialized bacteria detection element (i.e., a photodiode, PD). Therefore, the present disclosure proposes various types of bacteria detection sensors in order to increase the detection accuracy.

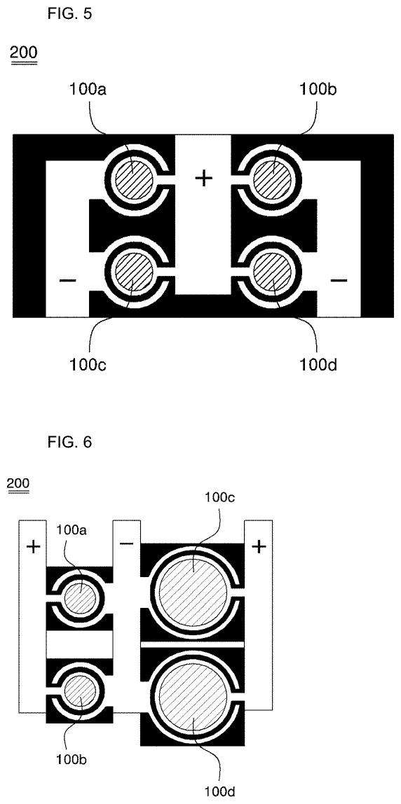

FIG. 5 is a layout view of a bacteria detection sensor composed of a plurality of identical bacteria detection elements. In FIG. 5, the exemplary view illustrates a bacteria detection sensor provided with the bacteria detection elements 100a, 100b, 100c, and 100d respectively having light absorption layers formed of the same material grown on the same substrate in the same process. The bacteria detection elements are arranged in a 2×2 array structure, and are arranged so that positive (+) power is supplied through a common electrode, and negative (−) power is supplied to each of the bacteria detection elements arranged in the left and right columns. Although the same bacteria detection elements are arranged in the 2×2 array structure in FIG. 5, it is natural that the bacteria detection elements may be variously formed in 3×3 and 4×4 array structures. When the bacteria detection sensor is formed by arranging the same bacteria detection elements in the array structure as described above, a large area may be detected, thereby reducing a detection error.

In the bacteria detection element, even when the light absorption layer is formed of the same material, the light-receiving efficiency and dark current vary depending on differences between light-receiving areas. The larger the light-receiving area of the bacteria detection element, the greater the frequency detection power, but conversely, the dark current (i.e., noise) also increases, so it is not easy to secure the optimal detection power with a bacteria detection sensor equipped with a single-size sensor. FIG. 6 is a layout view of a bacteria detection sensor in which bacteria detection elements respectively having different sizes of light absorption layers are formed in one package. The bacteria detection elements are arranged in an array structure, the bacteria detection elements being configured to respectively have the light absorption layers formed on the sapphire substrate by using the same process and the same material and respectively have light absorption layers of different areas. In the bacteria detection sensor 200 shown in FIG. 6, the bacteria detection elements 100a and 100b respectively provide with light absorption layers having a first area and the bacteria detection elements 100c and 100d respectively provided with light absorption layers having a second area are formed in the array structure.

Two different size bacteria detection elements are arranged in the 2×2 array structure, and are arranged so that positive (+) power is supplied through a common electrode, and negative (−) power is supplied to each of the bacteria detection elements arranged in the left and right columns. In the case of the exemplary embodiment shown in FIG. 6, since the dark current and the detected frequency intensity vary depending on the areas of the light absorption layers, there is an advantage in that it is possible to select and measure an appropriate one from among the dark current and the frequency intensity, which are output from the bacteria detection element. With a time difference, by sensing after supplying power to the bacteria detection elements 100a and 100b in the left column indicated by (1), and then by sensing after supplying power to the bacteria detecting devices 100c and 100d in the right column indicated by (2), more accurate sensing may be performed by comparing the above two sensed results.

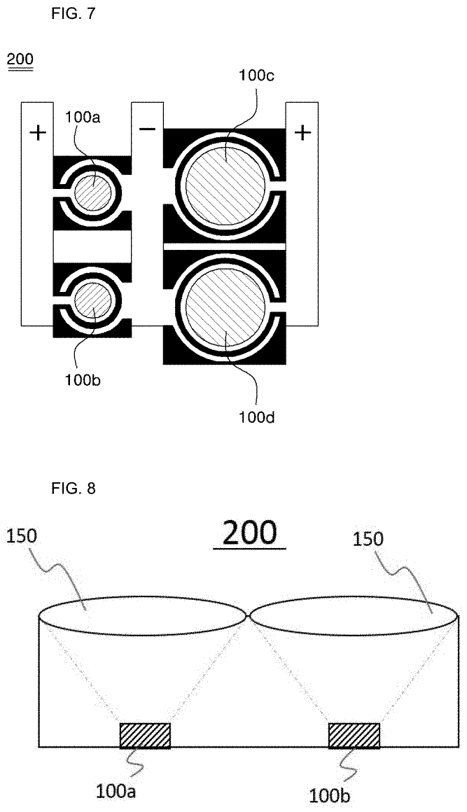

Furthermore, when at least two kinds of bacteria detection elements respectively having light absorption layers of various sizes and various material composition ratios are arranged in an array such as a 2×2 array, a 3×3 array, a 4×4 array, etc. on the sapphire substrate, there are advantages that a large area may be detectable while reducing errors and simultaneously monitoring various bacteria. FIG. 7 is a layout view of a bacteria detection sensor in which a first column is formed of bacteria detection elements 100a and 100b having a first light absorption layer, and a second column is formed of bacteria detection elements 100c and 100d having a second light absorption layer. When negative (−) power is supplied through the common electrode as shown in FIG. 7, and positive (+) power is respectively applied to the bacteria detection elements 100a and 100b provided in the left column and the bacteria detection elements 100c and 100d provided in the right column at different timings, frequencies may be obtained according to different detected bacteria from each bacteria detection element, so the bacteria may be detected more accurately. In the exemplary embodiment of FIG. 7, the bacteria detection elements respectively having the light absorption layers formed of the same material are formed to have the same size, but it is natural that each bacteria detection element may be formed in a different size.

FIG. 8 is a block diagram of a bacteria detection sensor provided with focusing lenses. A larger area may be detected by providing the focusing lens 155 above each of the bacteria detection elements 100a and 100b. Since light illuminating harmful substances (including bacteria) suspended in the air is focused, by the respective focusing lenses 155, to the bacteria detection elements 100a and 100b, a larger area may be monitored by using the focusing lenses 155.

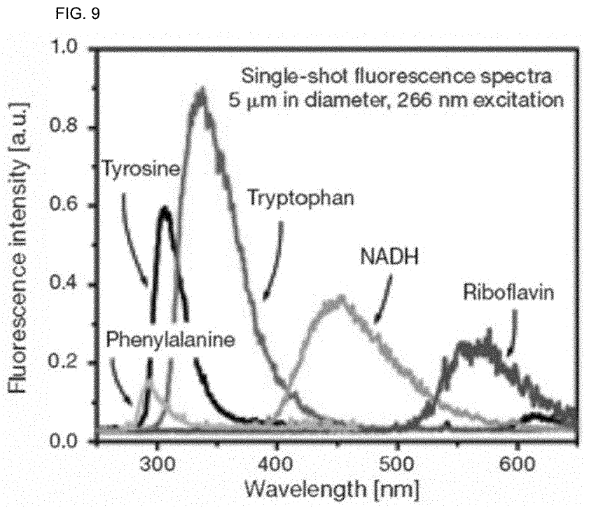

FIG. 9 is an intensity graph of fluorescence spectra excited by various bacteria or proteins when being illuminated with a 266 nm laser. It may be confirmed that when being illuminated with the 266 nm laser (having a diameter of laser light: 5 μm), light of different wavelengths is expressed from phenylalanine, tyrosine, tryptophan, nicotinamide adenine dinucleotide (NADA), and riboflavin. For reference, among the wavelengths of the UVC light source, it is known that wavelengths near 265 nm of light are the most appropriate wavelengths to destroy the cell walls of bacteria.

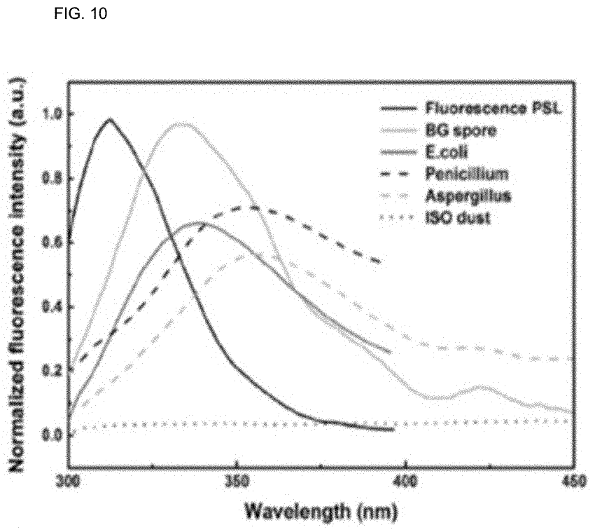

FIG. 10 is an intensity graph of normalized fluorescence spectra that are resonated, fluoresced, or scattered by various bacteria when being illuminated with a 278 nm (UVC) laser. It may be confirmed that when being illuminated with the UVC laser, different wavelengths are expressed in fluorescence photostimulable luminescence (PSL), bacillus globigii spores, E. coli, penicillium, aspergillus, and test dust (ISO dust). For reference, the test dust refers to the international standard IEC test dust (Mineral dust: ISO 12103-1 A2 Fine Dust). The test dust is expressed as an average of dust collection efficiency in each section with a dust particle size of 0.5 to 4.2 μm.

When light of wavelengths of 230 to 280 nm (belonging to UVC wavelengths) is emitted to protein (containing tryptophan) with E. coli, fluorescence wavelengths in a range of 340 to 360 nm (belonging to UVA wavelength) are simultaneously expressed. For reference, UVA light has a wavelength range of 320 to 400 nm, and UVC light has a wavelength range of 100 to 280 nm. It may be confirmed that as shown in FIG. 9, when a chunk of meat (containing tryptophan) is illuminated with light of 266 nm in a range of 230 to 280 nm (UVC), light of a wavelength of about 350 nm is expressed, and as shown in FIG. 10, when E. coli is illuminated with light of 278 nm in the range of 230 to 280 nm (UVC), a fluorescence wavelength of about 340 nm is expressed. Accordingly, in the case of the chunk of meat containing E. coli, it is difficult to distinguish whether E. coli is attached to the chunk of meat, only by the expressed wavelengths. In the present disclosure, whether the protein contains E. coli bacteria may be determined by the following detection method.

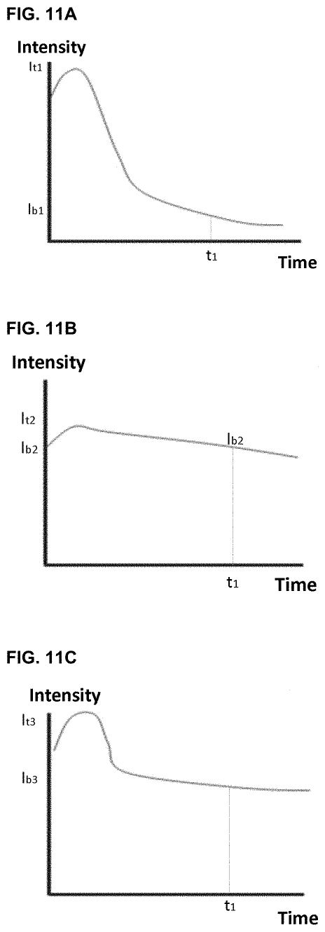

The principle of detecting E. coli contained in the protein in the present disclosure will be briefly described. FIG. 11A is a graph in which E. coli is illuminated with light of wavelengths of 230 to 280 nm (UVC) and the intensity of the light expressed over time is measured. When E. coli is illuminated with UVC light, E. coli is killed while emitting a fluorescence wavelength, thereby showing characteristics that the intensity of the fluorescence wavelength decreases relatively quickly over time. As shown in FIG. 11A, when E. coli is illuminated with UVC, the highest peak intensity of the expressed fluorescence is measured as It1, and the intensity of light measured after time t1 after emitting the UVC light is measured as Ib1.

FIG. 11B is a graph in which the intensity of light expressed over time by illuminating a chunk of meat not containing E. coli with 230 to 280 nm (UVC) light is measured. It may be confirmed that the protein (tryptophan) in the chunk of meat shows the characteristic that the fluorescence wavelength emission volume does not decrease significantly even with time because the DNA present in surroundings of the protein is continuously supplied even when the chunk of meat is illuminated with UVC. As shown in FIG. 11B, when a chunk of meat not containing E. coli is illuminated with UVC, the highest peak intensity of the expressed fluorescence is measured as It2, and the intensity of light measured after time t1 after emitting the UVC light is measured as Ib2.

FIG. 11C is a graph in which the intensity of light expressed over time is measured after illuminating the chunk of meat containing E. coli with light at 230˜280 nm (UVC). As shown in FIG. 11C, it may be confirmed that the intensity graph of the output light of the chunk of meat containing E. coli is displayed in a form of overlapping the graphs of FIGS. 11A and 11B. As shown in FIG. 11C, when the chunk of meat containing E. coli is illuminated with UVC, the highest peak intensity of the expressed fluorescence is measured as It3, and the intensity of light measured after time t1 after emitting the UVC light is measured as Ib3.

In the graphs of FIGS. 11A to 11C, theoretically, an equation It3=It1+It2 and an equation Ib3=Ib1+Ib2 are established. In addition, a relational expression such as Equation 1 is established.

δ1=Iₜ₁−I_{b1},

δ2=Iₜ₂−I_{b2},

δ3=Iₜ₃−I_{b3},

δ1>δ3>δ2 [Equation 1]

That is, when test objects are illuminated with a UVC light source, as shown in FIGS. 11A to 11C, it may be confirmed that result values obtained by subtracting the intensity value measured at time t1 from the maximum value of the fluorescence wavelength intensity expressed from tryptophan and E. coli has the largest value (δ1) in a case of E. coli, has the next largest value (δ3) in a case of the chunk of meat containing E. coli, and has the smallest value (δ2) in a case of the chunk of meat not containing E. coli. When the test objects are illuminated with the UVC light source by using such characteristics and the intensity of the expressed UVA light source is measured, whether E. coli is contained in the chunk of meat may be identifiable.

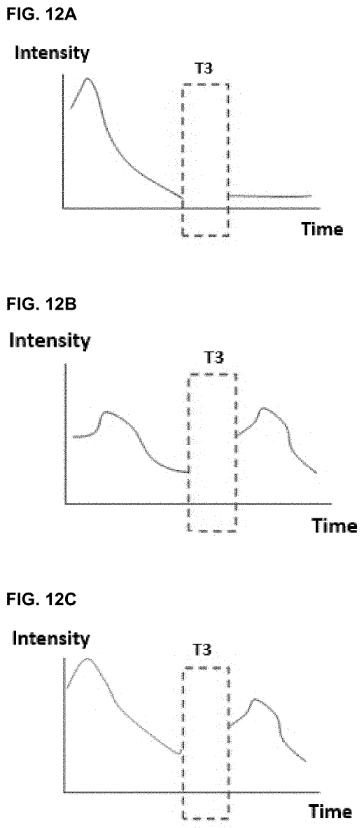

In a case where only E. coli is present, when sophisticated values for 61, 62 and 63 are established by means of artificial intelligence (AI) by preparing bulk samples for a chunk of meat not containing E. coli and a chunk of meat containing E. coli and conducting the learning, the intensity of the UVA light source expressed therefrom after illuminating the test objects only once is measured, whereby whether or not E. coli is attached to the chunk of meat may be confirmed. 15 FIGS. 12A to 12C are graphs illustrating a method of detecting whether E. coli is contained or not by emitting UVC twice and using the characteristics identified through FIGS. 11A to 110. FIGS. 12A to 12C are graphs of intensity changes measured over time when illuminating each of E. coli, protein, and protein with E. coli twice with the UVC light source, the respective illuminating having a rest period therebetween. In the present disclosure, UVC is emitted a first time with an intensity of 6 mW to 10 mW by using the above characteristics, and then UVC is emitted again with the same intensity a second time after going through a rest period (T3) for a predetermined period of time, so as to use the fluorescence wavelength that is expressed, thereby determining whether the chunk of meat contains E. coli.

In the case of E. coli only, the intensity of the wavelength detected by the second time UVC emission is very small, unlike the first time UVC emission (in FIG. 12A). This is because E. coli is killed by the first time illumination with the UVC light source. In contrast, in the case of protein only, similar to the first time UVC emission, similar intensity of wavelength is also detected in the second time UVC emission (in FIG. 12B). In the case of E. coli-attached protein, the intensity is expressed in similar graphs in the first time UVC emission and the second time UVC emission, but since E. coli is killed by the first time UVC emission, a graph pattern with a lower intensity than the intensity expressed by the first time UVC emission is shown in the second time UVC emission. In the case of FIGS. 12A to 12C as well, when the graph pattern expressed for each of the cases is learned by artificial intelligence (AI), E. coli in the chunk of meat may be detected. In addition, by changing the output power of excitation light source and measuring for various cases, the accuracy may be improved.

It is natural that the principle described with reference to FIGS. 11A to 11C and FIGS. 12A to 12C may be applied to similar cases. FIGS. 11A to 11C and FIGS. 12A to 12C describe the detection method for the cases in which the frequencies of light expressed in tryptophan and E. coli are in almost the same range and may not be distinguished from each other. Accordingly, such detection principle is not limited to tryptophan and E. coli, and it is natural that the detection principle may be generally applied to relationships between test substances and bacteria, which express the same fluorescence wavelength when being illuminated with a UVC light source. Here, the test substance may be understood as a substance to which bacteria may adhere, such as a chunk of meat.

E. coli attached to a chunk of meat is usually attached to the surfaces of the chunk of meat in many cases. In contrast, tryptophan contained in a chunk of meat is contained inside the chunk of meat unlike the case of E. coli. Due to this positional difference, when illuminating the chunk of meat, to which E. coli is attached, with UVC light source, the fluorescence wavelength expressed by the resonance of E. coli tends to appear earlier than the fluorescence wavelength expressed by tryptophan. E. coli may also be detected by using this expression time difference. Unfortunately, the graphs of FIGS. 11A to 11C and FIGS. 12A to 12C are not shown accurately enough to recognize such a detection time difference.

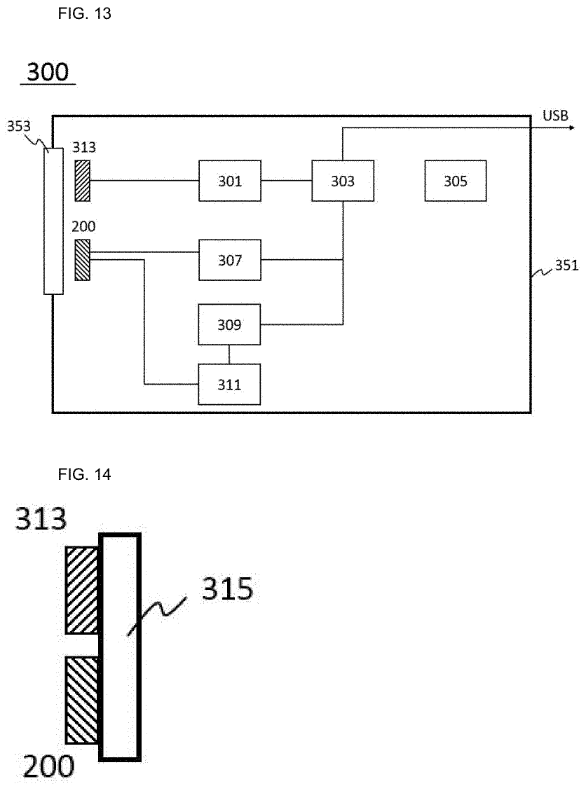

FIG. 13 is a system configuration diagram of an electronic device provided with the bacteria detection sensor according to the present disclosure. An electronic device 300 having a bacteria detection sensor is configured such that various components are built in a casing 351 provided with a window 353. The window 353 may be formed of quartz glass that minimizes UV attenuation or may be formed as a through-hole formed as an empty space. The conventional electronic device provided with a bacteria detection sensor has a complicated system configuration because a light-emitting part for emitting excitation light to bacteria and the bacteria detection sensor for receiving light of fluorescence expressed by bacteria are respectively mounted on separate printed circuit boards. As shown in FIG. 14, in the present disclosure, an excitation light emission part 313 and the bacteria detection sensor 200 are configured to be all mounted on a single printed circuit board 315, so that the system configuration is simple. In addition, the embodiment of the present disclosure is configured to not only detect bacteria but also provide sterilization of bacteria by emitting UVC light when bacteria are detected.

The excitation light emission part 313 is a light source module for emitting UVC light, and in the present disclosure, the excitation light emission part 313 is mounted on a single printed circuit board 315 together with the bacteria detection sensor 200. A DC-DC converter 305 is a circuit part that converts a voltage of externally supplied power into a driving voltage for driving various circuit elements constituting the electronic device 300. The DC-DC converter 305 supplies power to various circuit elements constituting the electronic device 300. A system controller 303 is a module that provides control signals for controlling various circuit elements constituting the electronic device 300. A UVC power controller 301 is a module for controlling turning on/off of power supplied to the excitation light emission part 313, and a UVA power controller 307 is a module for controlling turning on/off of power supplied to the bacteria detection sensor 200. An amplifier 311 is a circuit element that amplifies a voltage output from the bacteria detection sensor 200, and an AD converter 309 is a circuit element that converts the amplified voltage into a digital value. In the present disclosure, the voltage amplified by the amplifier 311 is designed to be output as a value between 0 V to 3 V, and the AD converter 309 is designed to digitize an analog voltage output from the amplifier 311 into 12 sections for providing the voltage.

The system controller 303 may provide the UVC power controller 301 with a first UVC control signal for driving the excitation light emission part 313 with a first intensity and a second UVC control signal for driving the excitation light emission part 313 with a second intensity (having a value greater than that of the first intensity). It is designed such that the first intensity is intensity at which bacteria resonate, and the second intensity is intensity at which the bacteria of which the cell walls are destroyed are killed while resonating, so that both bacteria detection and bacterial removal may be performed.

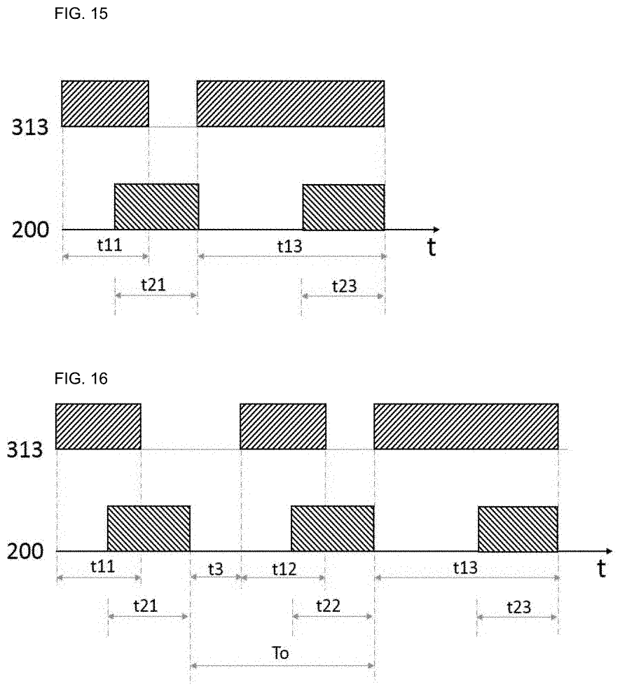

FIG. 15 is a driving timing diagram of the excitation light emission part and the bacteria detection sensor constituting the electronic device shown in FIG. 13. During time t11, the excitation light emission part 313 is turned on to illuminate the sample with UVC. During time t21, the bacteria detection sensor 200 is turned on to detect fluorescence expressed by bacteria contained in the sample, whereby bacteria are sensed. A t21 section will be referred to as a bacteria sensing section. Since the excitation light emission part 313 emits UVC light and the bacteria detection sensor 200 does not respond to light in the corresponding UVC range, there is no problem to have time t11 (i.e., the UVC emission section) and time t21 (i.e., the bacteria sensing section) of which the respective sections thereof partially overlap with each other, as shown in FIG. 15.

The electronic device provided with the bacteria detection sensor shown in FIG. 13 may implement a function as well that removes the detected bacteria. When bacteria are detected, a sterilization process may be performed by operating the excitation light emission part 313 with greater power for a long period of time during time t13. When time t13 (i.e., a sterilization section) has elapsed to some extent, the bacteria detection sensor 200 is operated for time t23 (i.e., a bacteria death determination section) so as to detect bacteria and determine whether bacteria are completely killed. When it is determined that bacteria are completely killed as a result of the determination, the operations of the excitation light emission part 313 and the bacteria detection sensor 200 are stopped.

In a case of expressing the wavelengths in the same range in response to UVC light as in the case of protein and E. coli, time t11 (the UVC emission section) and time t21 (the bacteria sensing section) may be repeatedly performed once more. FIG. 16 is a driving timing diagram of the excitation light emission part and bacteria detection sensor for applying the electronic device shown in FIG. 13 to the test object and bacteria that express the same range of wavelengths in response to the UVC light. As shown in FIG. 16, after time t11 (the UVC emission section) and time t21 (the bacteria sensing section), the rest period t3 is passed, and then t12 time (the UVC emission section) and t22 time (the bacteria sensing section) are performed once more.

As described above, the preferred exemplary embodiments of the present disclosure have been described and illustrated by using specific terminology, but such terminology is only for the purpose of clearly describing the present disclosure, and thus it is apparent that various modification and changes may be made to the exemplary embodiments and the described terms of the present disclosure without departing from the spirit and scope of the following claims. Such modified exemplary embodiments should not be individually understood from the spirit and scope of the present disclosure, but should be considered to fall within the scope of the claims of the present disclosure.

What is claimed is:

1. A bacteria detection element, comprising:
a substrate;
a first semiconductor layer and a second semiconductor layer configured to be arranged on the substrate and made of a nitride-based material; and
a light absorption layer configured to be arranged between the first semiconductor layer and the second semiconductor layer and made of the nitride-based material, so as to absorb light of multiple wavelengths,
wherein the light absorption layer comprises:
a first light absorption layer configured to absorb light of a first wavelength;
a second light absorption layer configured to absorb light of a second wavelength different from the first wavelength; and
a third light absorption layer configured to absorb light of a third wavelength different from the first and second wavelengths,
the first to third light absorption layers are configured to be formed of a single component of AlGaN, be arranged between the first semiconductor layer and the second semiconductor layer, and respectively have Al composition ratios increasing in an order of the first light absorption layer, the third light absorption layer, and the second light absorption layer, so as to absorb the light of the first to third wavelengths incident on the first semiconductor layer or the second semiconductor layer separately from each other,
the first semiconductor layer, the light absorption layer, and the second semiconductor layer are respectively provided with inclined surfaces in a mesa structure, and
the inclined surfaces are passivated with an oxide.

2. The bacteria detection element of claim 1, wherein the first wavelength is longer than the second wavelength, and
the third light absorption layer absorbs the light of the third wavelength shorter than the first wavelength and longer than the second wavelength.

3. The bacteria detection element of claim 2, wherein the substrate is a sapphire substrate, and further comprises:
an AlN template configured to be formed with a first AlN layer grown through changing a growth temperature from 800° C. to 1,100° C. on an upper part of the sapphire substrate, and be formed with a second AlN thin film grown at a high temperature of 1,250° C. on an upper part of the first AlN layer.

4. The bacteria detection element of claim 3, wherein a doping concentration of the second semiconductor layer is 1×10¹⁸ cm⁻³.

5. A bacteria detection sensor formed with an integrated package of a plurality of bacteria detection elements of claim 1, the bacteria detection sensor comprising:
the plurality of bacteria detection elements configured to be produced to respectively have same size light absorption layers on a same substrate in a same semiconductor process.

6. The bacteria detection sensor of claim 5, further comprising:
a focusing lens provided above each bacteria detection element.

7. A bacteria detection sensor formed with an integrated package of a plurality of bacteria detection elements of claim 1, the bacteria detection sensor comprising:
the plurality of bacteria detection elements configured to be formed on a same substrate in a same semiconductor process, and comprising at least one bacteria detection element having a light absorption layer having a different area.

8. The bacteria detection sensor of claim 7, further comprising:
a focusing lens provided above each bacteria detection element.

9. A bacteria detection sensor formed with an integrated package of a plurality of bacteria detection elements of claim 1, the bacteria detection sensor comprising:
the plurality of bacteria detection elements configured to be formed on a same substrate in a same semiconductor process, and comprising at least one bacteria detection element having a light absorption layer formed in a different composition ratio.

10. A bacteria detection sensor formed with an integrated package of a plurality of bacteria detection elements of claim 1, the bacteria detection sensor comprising:
the plurality of bacteria detection elements configured to be formed on a same substrate in a same semiconductor process, comprising at least one of each bacteria detection element having a light absorption layer formed in a different composition ratio, and comprising at least one of each bacteria detection element having the light absorption layer formed in a different area.

11. An electronic device provided with a bacteria detection sensor, the electronic device comprising a casing provided with a window on one side thereof, and comprising, in the casing:
the bacteria detection sensor comprising a bacteria detection element of claim 1;
a UVA power controller configured to control power supplied to the bacteria detection element on or off;
an excitation light emission part configured to illuminate with a UVC light source;
a UVC power controller configured to control power supplied to the excitation light emission part on or off;
an amplifier configured to amplify a signal output from the bacteria detection sensor;
an AD converter configured to convert the signal amplified by the amplifier into a digital signal; and
a system controller configured to generate a control signal for controlling the UVA power controller, the UVC power controller, and the AD converter, and output the digital signal output from the AD converter to outside.

12. The electronic device of claim 11, wherein the excitation light emission part and the bacteria detection sensor are mounted on a single printed circuit board.

13. The electronic device of claim 12, wherein the system controller provides the UVC power controller with a first UVC control signal for driving the excitation light emission part with a first intensity and a second UVC control signal for driving the excitation light emission part with a second intensity (having a value greater than that of the first intensity),
the first intensity is an intensity at which bacteria resonate, and
the second intensity is an intensity at which the bacteria are removed.

14. A method of detecting whether bacteria are attached on a test object, the method having the test object and the bacteria provided with a characteristic of expressing a fluorescence wavelength in a same range when being illuminated with a UVC light source, and comprising:
a first step of illuminating a first time the test object with the UVC light source;
a second step of identifying an intensity change pattern according to a passage of time of a UVA wavelength expressed from the test object by the first time illumination with the UVC light source;
a third step of stopping the first time illumination with the UVC light source of the first step for a predetermined period of time after the second step;
a fourth step of illuminating a second time the test object with the UVC light source;
a fifth step of identifying an intensity change pattern according to the passage of time of the UVA wavelength expressed from the test object by the second time illumination with the UVC light source; and
a sixth step of determining whether or not the bacteria are attached to the test object through comparison of the intensity change patterns identified in the second step and the fifth step.

15. The method of claim 14, wherein an overlapping region exists between a section in which the first time illumination with the UVC light source of the first step is performed and a section in which the intensity change pattern according to the passage of time of the UVA wavelength expressed from the test object in the second step is identified, and
an overlapping region exists between a section in which the second time illumination with the UVC light source of the fourth step is performed and a section in which the intensity change pattern according to the passage of time of the UVA wavelength expressed from the test object in the fifth step is identified.

16. The method of claim 14, wherein when the intensity change patterns identified in the second step and the fifth step coincide with each other within an error range in the sixth step, and when an intensity measured at each step does not differ within the error range, the bacteria are determined not to be attached to the test object.

17. The method of claim 14, wherein when the intensity change patterns identified in the second step and the fifth step coincide with each other within the error range in the sixth step, but when an intensity measured in the second step is detected to be greater than an intensity measured in the fifth step, the bacteria are determined to be attached to the test object.

18. A method of detecting whether bacteria are attached on a test object, the method having the test object and the bacteria provided with a characteristic of expressing a fluorescence wavelength in a same range when being illuminated with a UVC light source, and comprising:
a first step of calculating a first difference value (δ1) by subtracting an intensity value of a fluorescence wavelength measured at time t1 after illumination with the UVC light source from a highest value of a fluorescence wavelength expressed by illuminating the bacteria with the UVC light source, and calculating a second difference value (δ2) by subtracting the intensity value of the fluorescence wavelength measured at time t1 after the illumination with the UVC light source from a highest value of a fluorescence wavelength expressed by illuminating the test object to which the bacteria are not attached with the UVC light source;
a second step of calculating a third difference value (δ3) by subtracting the intensity value of the fluorescence wavelength measured at time t1 after the illumination with the UVC light source from a highest value of the fluorescence wavelength expressed by illuminating the test object, whose attachment of the bacteria is not confirmed, with the UVC light source; and
a third step of determining whether the bacteria are attached to the test object in the third step by using the first difference value, the second difference value, and the third difference value.

19. The method of claim 18, wherein when the third difference value (δ3) is in a range of values greater than the second difference value (δ2) and smaller than the first difference value (δ1) in the third step, the bacteria are determined to be attached to the test object of the third step.
